(19) United States
(12) Patent Application Publication
(10) Pub. No.: US 2015/0327379 A1
(43) Pub. Date: Nov. 12, 2015

(54) BED MOUNTED INTERACTIVE DISPLAY SYSTEM

(71) Applicants: Kaci Prunty, Lexington, KY (US); Melissa W. Lassiter, Chamblee, GA (US); Jeffrey S. Reckseidler, San Antonio, TX (US); Stephanie M. Janssen, Villa Rica, GA (US); Matthew G. Lancaster, Atlanta, GA (US); Kraig N. Mooney, Atlanta, GA (US); Tom L. Jordan, Marietta, GA (US)

(72) Inventors: Kaci Prunty, Lexington, KY (US); Melissa W. Lassiter, Chamblee, GA (US); Jeffrey S. Reckseidler, San Antonio, TX (US); Stephanie M. Janssen, Villa Rica, GA (US); Matthew G. Lancaster, Atlanta, GA (US); Kraig N. Mooney, Atlanta, GA (US); Tom L. Jordan, Marietta, GA (US)

(21) Appl. No.: 14/275,369

(22) Filed: May 12, 2014

(51) Int. Cl. H05K 5/02; H05K 5/00

(52) U.S. Cl. CPC H05K 5/0204; H05K 5/0017

(57) ABSTRACT

An interactive product display system includes a display unit for displaying media regarding a product and a mounting structure for mounting the display unit to the product in a manner that allows a user to change an orientation of the display unit based on a position of the user.

### CROSS-REFERENCE TO RELATED APPLICATION

The present invention claims the benefit of U.S. Ser. No. 61/821,841, filed May 10, 2013, the disclosure of which is incorporated herein.

### BACKGROUND AND SUMMARY OF THE INVENTION

Sleep is an important contributor to overall wellness. The present invention is directed to a bed mounted interactive display system that enables potential bed purchasers to view various media presentations regarding the bed. The invention is thus effective in conveying information about features of the bed while the potential purchasers are interacting with the bed. In this regard, how the design and construction of the bed contributes to deeper and restorative sleep can be communicated directly from the bed manufacturer to the potential purchaser. While the interaction between the purchaser and a retail sales associate is not eliminated, the invention facilitates a direct communication with the purchaser. This direct communication enables the bed manufacturer to share how the bed can contribute to an improvement in sleep and thus the overall wellness of the purchaser.

In one aspect of the invention, the bed mounted interactive display system enables the viewing of media presentations while a potential purchaser is reclined on the bed. The display system, in one preferred embodiment, includes a touch-screen display unit having a display screen that responds to tactile inputs to direct the purchaser through a user experience or provide information regarding the bed. The display system is removably attached to the bed, such as at the bed frame and thus can be detached and then attached to a new bed should the need arise.

In another aspect of the invention, the bed mounted interactive display system sits atop the bed and has a tactile display unit that allows a user to direct the display of content regarding the bed. The display system is configured such that the display unit can be rotated between multiple viewing positions.

Various other features, objects and advantages of the invention will be made apparent from the following description taken, together with the drawings.

### BRIEF DESCRIPTION OF THE DRAWINGS

The drawings illustrate the best mode presently contemplated of carrying out the invention.

In the drawings:

FIG. 1 is a partial isometric view an interactive display system shown mounted to a bed;

FIG. 2 is an isometric view of the interactive display system of FIG. 1;

FIG. 2A is an exploded view of a portion of FIG. 2 taken along line A-A of FIG. 2;

FIG. 3 is a side elevation view of the interactive display system of FIG. 2;

FIG. 4 is an end elevation view of the interactive display system of FIG. 2;

FIG. 5 is a partial isometric view of an interactive display system according to an alternate embodiment of the invention shown mounted to a bed;

FIG. 6 is an isometric view of the interactive display system of FIG. 5;

FIG. 7 is a side elevation view of the interactive display system of FIG. 6;

FIG. 8 is an end elevation view of the interactive display system of FIG. 6;

FIG. 9 is a partial isometric view of an interactive display system according to another embodiment of the invention;

FIG. 10 is a side elevation view of the interactive display system of FIG. 9;

FIG. 11 is an end view of the interactive display system of FIG. 9;

FIG. 12 is an isometric view of an interactive display system according to yet a further aspect of the invention and shown positioned atop a bed and in a first viewing position;

FIG. 13 is a rear isometric view of the interactive display system of FIG. 12;

FIG. 14 is an isometric view of the interactive display system of FIG. 12 shown in a second viewing position;

FIG. 15 is a front elevation view of the interactive display system of FIG. 12 in the first viewing position;

FIG. 16 is a side elevation view of the interactive display system of FIG. 15; and.

FIG. 17 is a rear elevation view of the interactive display system of FIG. 12 in the first viewing position.

### DETAILED DESCRIPTION

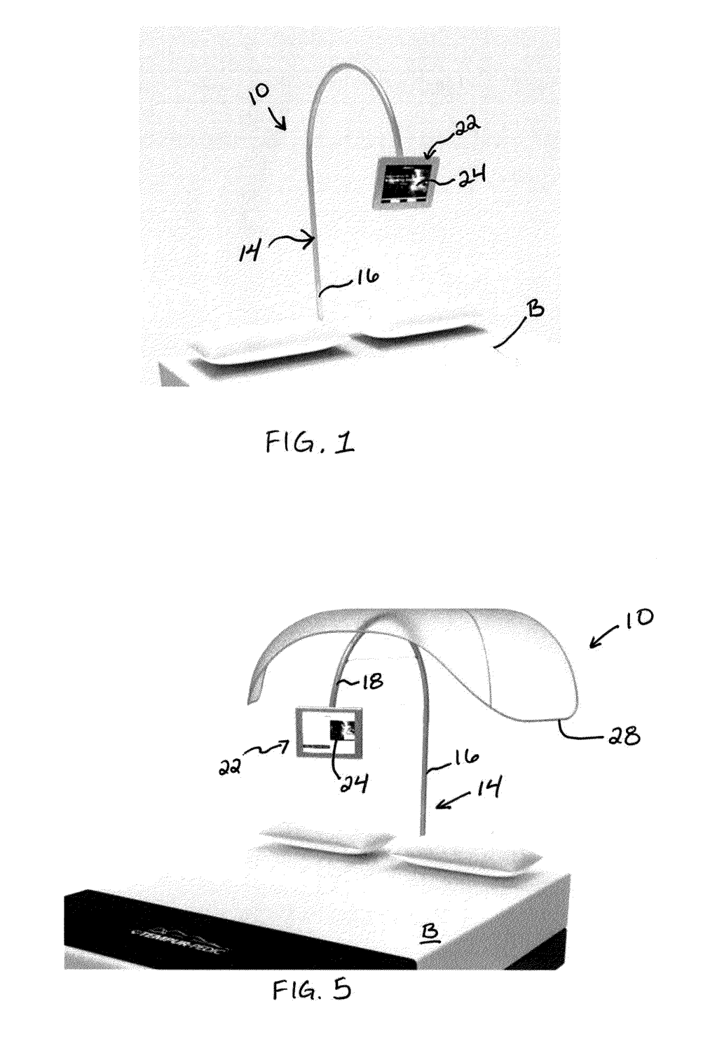

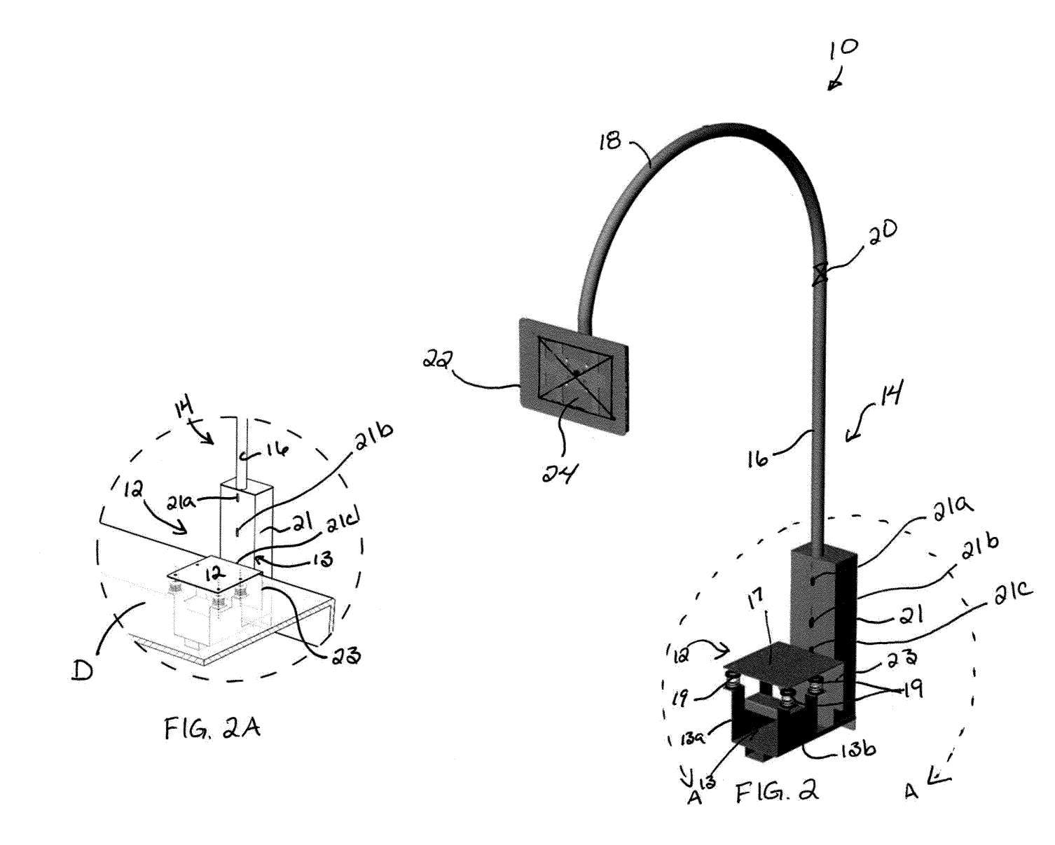

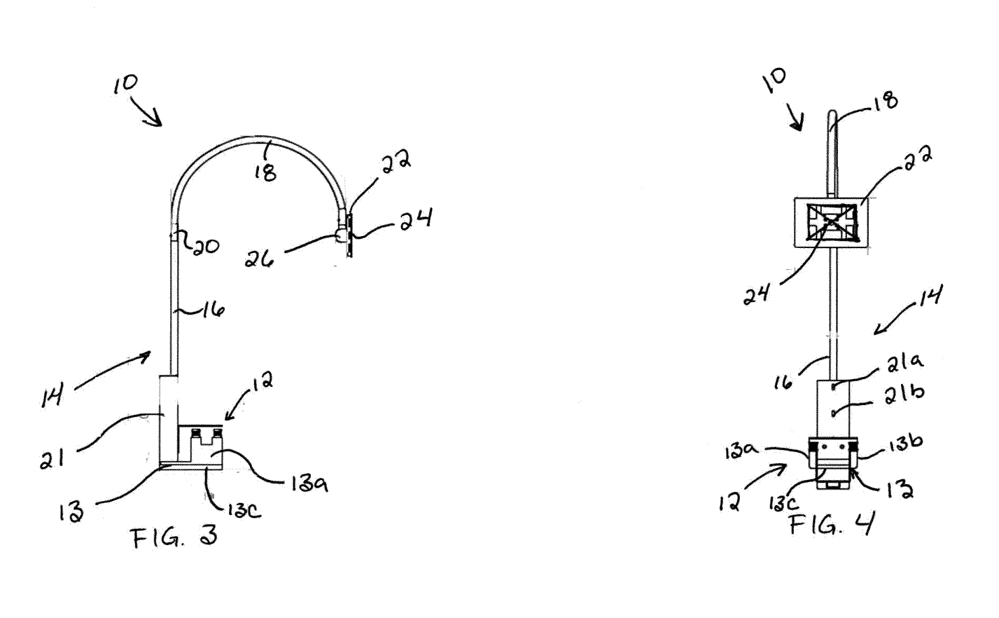

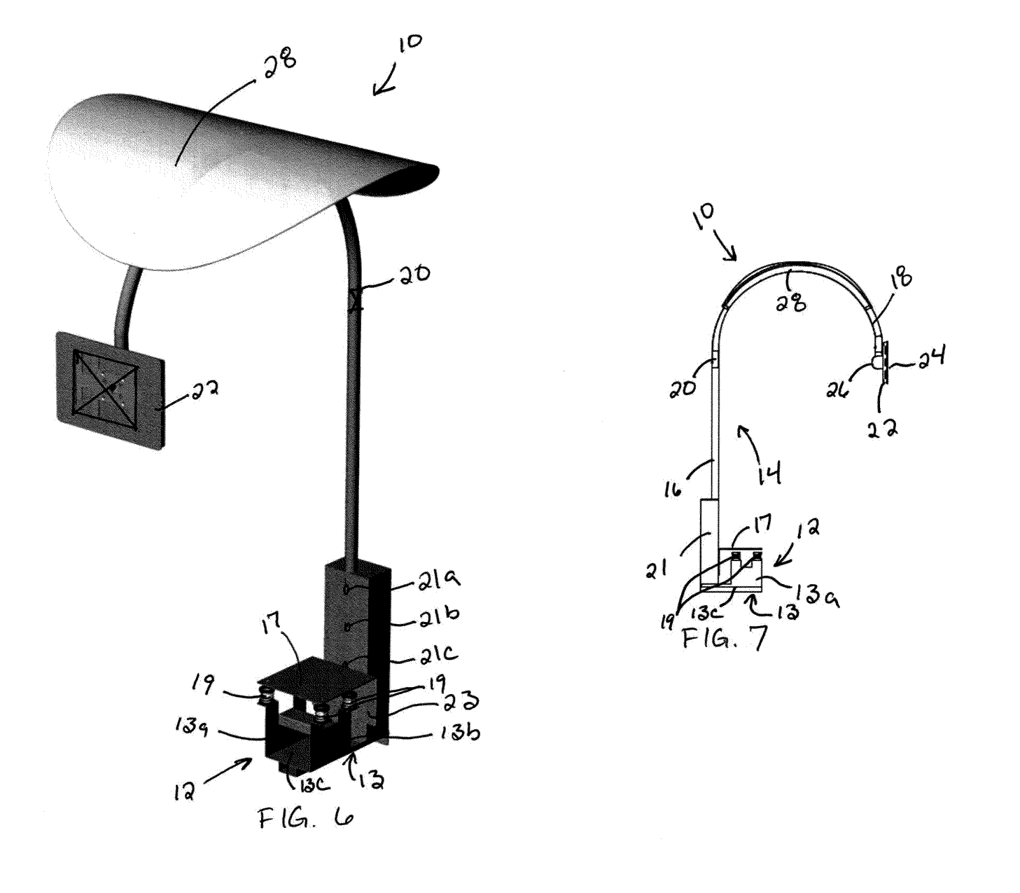

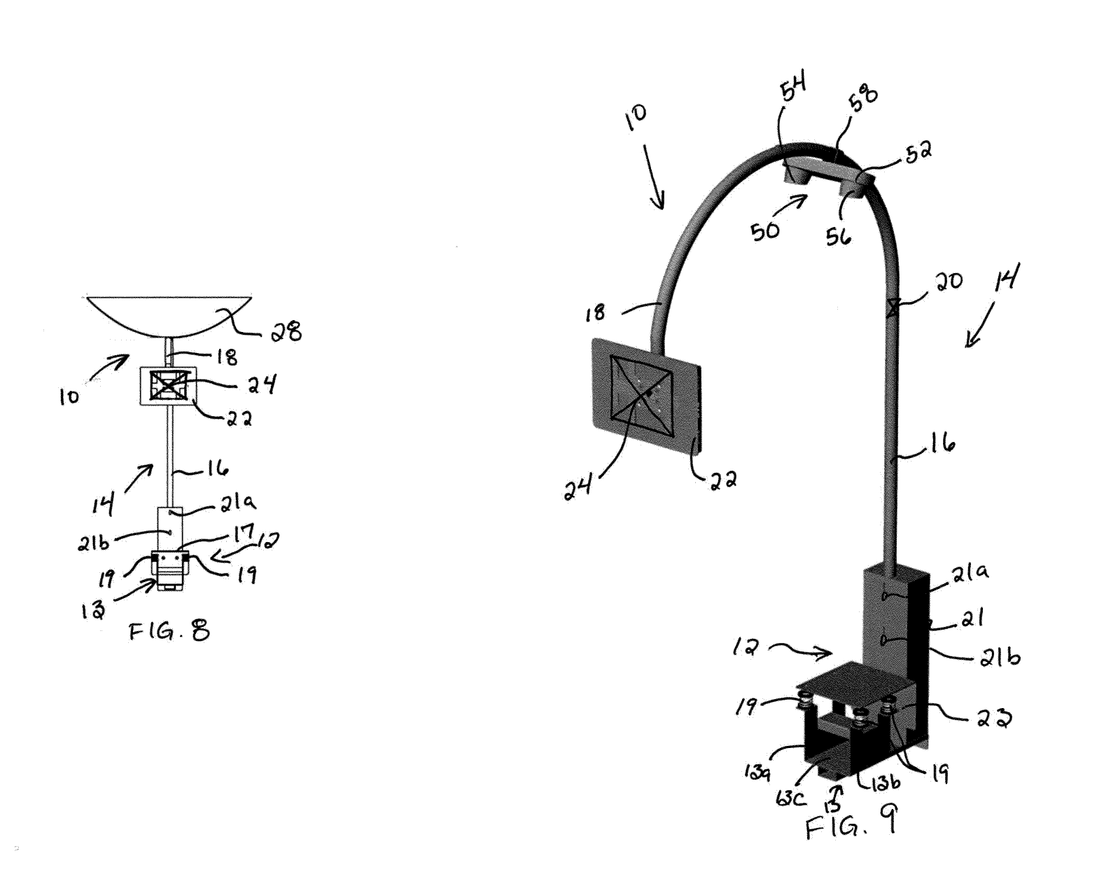

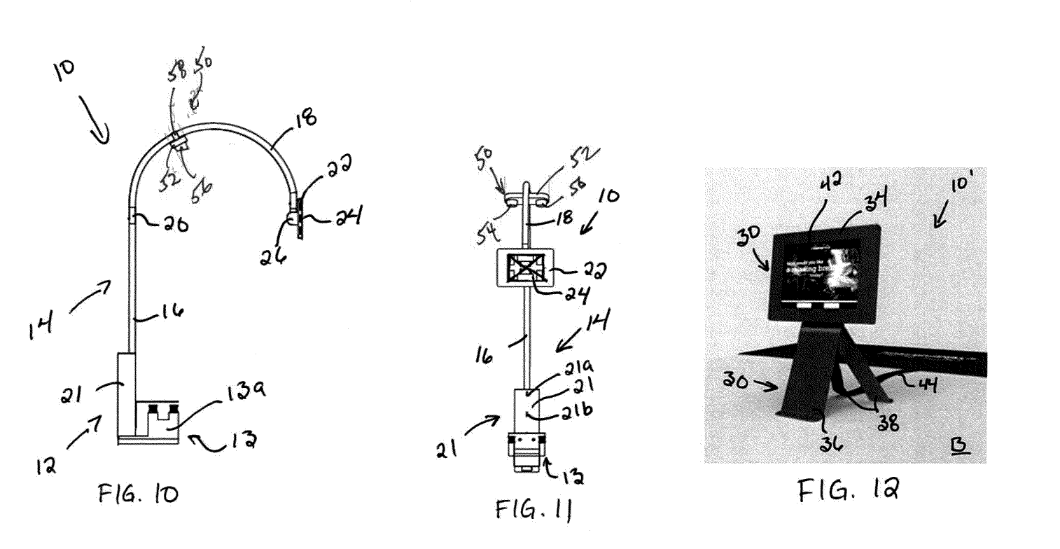

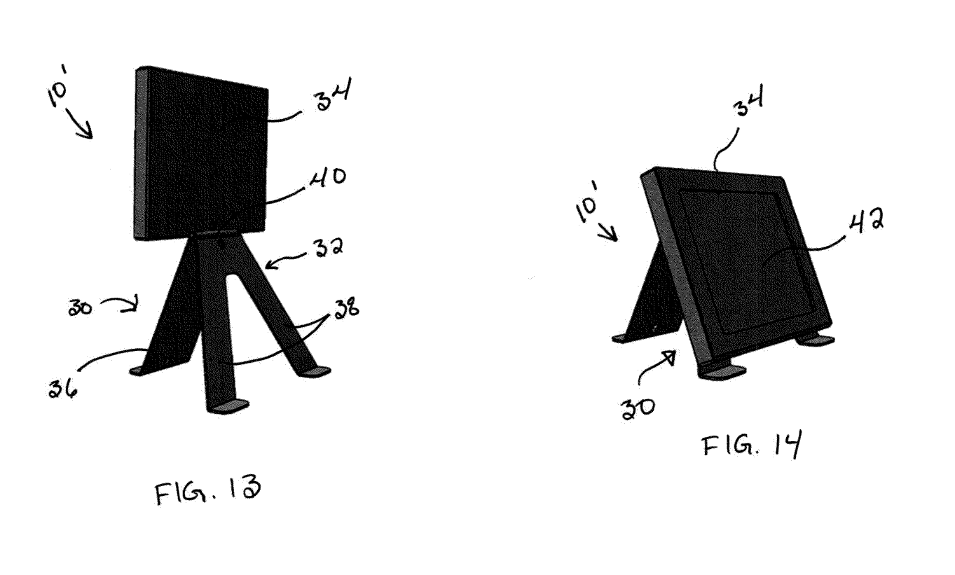

Turning now to FIGS. 1-4, the bed mounted interactive display system (“system”) 10 for facilitating the viewing of media regarding product to which the display system is mounted is described. The display system 10 is generally comprised of base 12 for mounting the system 10 to a bed, foundation, or adjustable base, and an elongated portion, e.g., stanchion 14, extending uprightly from the base 12. In a preferred embodiment, the stanchion 14 is hollow to thereby define an elongate chamber. The stanchion 14 has an upright lower arm 16 that is pivotably connected to an upper arm 18. A pivot joint 20 interconnects arms 16, 18 and allows the upper arm 18 to rotate about an axis of rotation defined through the elongated length of the lower arm 16.

A housing 22 is pivotably mounted to free end of the upper arm 18. The housing 22 is sized to hold an interactive display device or panel 24, such as an iPad® or other tablet. In a preferred embodiment, the housing 22 securely retains the display panel 24 such that a key or similar device is required to detach or remove the display panel 24 from the housing 22. The rotatable interconnection between the lower arm 16 and the upper arm 18 allows a user to easily position the display panel 24 at one of several positions about an arc (not numbered) defined by the arc of rotation of the upper arm 18 relative to the lower arm 16.

The display housing 22 is mounted to the free end of the upper arm 18 by a joint 26, such as ball joint, that allows rotation of the display housing 22 relative to the upper arm 18. In this regard, the display panel 24 may be tilted or otherwise moved to a user desired or preferred position, such as to improve viewing angle when the user is lying on the bed or mattress B (FIG. 1). The housing 22 preferably includes a data port (not shown), e.g., USB interface, as known in the art, to which the display panel 24 is connected for supplying electrical power to the display panel 24. In this regard, an electrical cord (not shown) is routed through an internal elongated cavity formed within the stanchion 14.

In a preferred embodiment, the joint 26 allows full rotation of the display housing 22 as well as tilting of the display housing 22. In this regard, when not in use by a potential purchaser, the display housing 22 can be rotated to a position such that the display panel 24 faces outward or away from the head of the bed. In this position, potential purchasers are able to view media, such as product advertisements, promotions, commercials, product demonstrations, etc., on the display panel 24 while walking past the bed in a showroom environment. However, when a purchaser wants to view the media while reclined on the bed, the display panel can be rotated to “face” the head of the bed and, if desired, tilted to provide a better viewing angle for a viewer when in a supine or reclined position.

Referring briefly to FIGS. 2 and 2A, the base 12 has a mounting bracket 13 that in the illustrated embodiment includes a pair of upright bracket members 13a, 13b joined at lower ends thereof by a plate 13c. The bracket 13 is constructed to be mounted to a bed frame (not shown) or, in a more preferred embodiment, the decking D of an adjustable bed base. When attached to the decking D, the interactive display system 10 will move with articulation of the base and thus maintain easy user viewing as the bed is articulated between positions with minimal adjustment, if any, by the user.

The bracket 13 further includes a mounting plate 17 that is secured to upper ends of the bracket members 13a, 13b by four dampers (three of which are viewable in the figure). The mounting plate 17 is attached to the decking D via screws (not shown), for example, to secure the bracket 13, and thus the interactive display system 10, to the decking D. The dampers 19, e.g., dampening springs, allow the pressure placed on the mounting plate 17 to be partially absorbed when a mattress is placed upon the decking D and/or when the adjustable base is articulating.

With particular reference to FIG. 2A, the mounting bracket 13 is removably secured to a mounting block 21. The mounting block 21 defines multiple mounting positions 21a, 21b, 21c, for example, for the mounting bracket 13 to allow for selectability in the height of the interactive display system 10. In this regard, the mounting plate as a mounting leg 23 with lugs (not shown) for slidably engaging the holes 21a, 21 b, 21c that define the selectable mounting positions. The lugs are received in the holes in a conventional manner, such as, slide and lock. As further shown in FIG. 2A, the mounting plate 17 and the mounting leg 23 engage an outer surface of the decking D.

Turning now to FIGS. 5-8, the display system 10 may include a canopy 28 that is attached to the stanchion 14, i.e., upper arm 18. The canopy, which is preferably translucent or opaque, provides a degree of privacy for a potential purchaser as he or she rests atop the bed while viewing the media shown on the display panel 24. In a preferred embodiment, the canopy 28 is made of fabric but it is contemplated that other materials may be used, such as plastic.

With reference now to FIGS. 9-11, the interactive display system 10 may also include a speaker system 50. The speaker system 50, in one embodiment, includes a speaker housing 52 containing a pair of speakers 54, 56 oriented to project sound downward toward the bed B, and thus the user when such user is reclined on the bed B. A C-clamp 58 is used to secure the speaker housing 52 to upper arm 18. In one embodiment, the speakers 54, 56 are wireless speakers that receive signals from the tablet 24 via a wireless connection, e.g., Bluetooth® connection. Alternately, a wired communications link is used.

It will be appreciated that the interactive display system 10 may be outfitted without either the canopy or the speaker system, one of the canopy and the speaker system, or both the canopy and the speaker system.

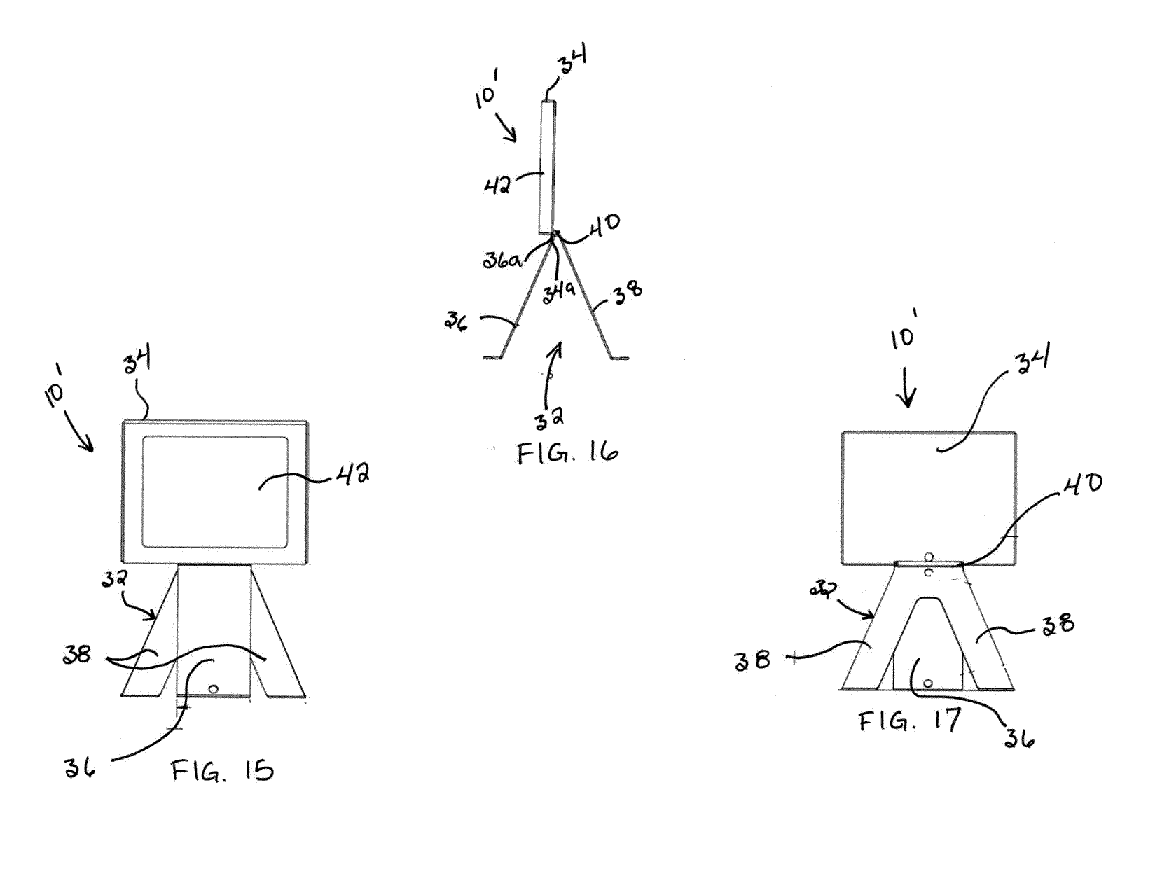

Referring now to FIGS. 12-17, an alternate configuration of an interactive display system in accordance with the present invention is shown. The system 10′ includes a top-of-bed mounted display unit 30 comprised of a base 32 to which a display housing 34 is pivotably mounted. The base 32 is comprised of a first leg portion 36 and a rear leg portion 38. The respective leg portions 36, 38 are interconnected by a hinge pin 40 to which the display housing 34 is also connected. The display housing 34 is designed to securely retain a display panel 42, such as a tablet that responds to tactile inputs. The display housing 34 includes a power and data connector, such as a USB interface (not shown), for providing power to the display panel 42. An electrical cord (not shown) is connected to the display housing 34 for providing electrical power to the interface. The electrical power cord is contained in a sheath 44 that can be routed along the top of the bed and ultimately to an electrical outlet.

The respective leg portions 36, 38 provide respective display positions for the display housing 34. In a preferred implementation, the system 10′ is placed atop a bed with the leg portions 36, 38 facing the head and foot ends of the bed, respectively. Leg portion 38 provides a seat against which the display housing 34 can rest when the display housing 34 is rotated from the upright position shown in FIG. 16 to the inclined position shown in FIG. 14. In the upright position, FIG. 16, the display housing 34 is held upright by the engagement of the lower edge 34a of the display housing resting upon the outer surface 36a of leg portion 36. It is understood that other ways may be used to secure the display panel 34 in the upright position, such as by a locking hinge pin.

As shown in FIG. 16, when the display housing 34 is in the upright position, the display panel 42 faces a first direction; yet, when the display housing 34 is rotated about hinge pin 40 such that the display panel is seated against leg portion 38, the display panel 42 will be facing in a second opposite direction. In a preferred embodiment, the display panel 42 has an accelerometer or similar orientation-detection device and can adjust the orientation of what is displayed thereon based in response to changes in positions of the display housing. Thus, the display housing 34 may be rotated between forward facing and rearward facing positions to accommodate the viewing angle of the user, e.g., potential purchaser.

Moreover, to attract the attention of a potential purchaser perusing a showroom or to otherwise broadcast media regarding the bed, the display housing 34 can be rotated to a foot-end facing position such that the display panel 42 faces outward or away from the head of the bed. In this position, potential purchasers are able to view media on the display panel 42 while walking past the bed in a showroom environment. However, when a purchaser wants to view the media while reclined on the bed, the display panel 42 can be rotated to “face” the head of the bed.

In one preferred embodiment of the invention, the systems described herein include firmware and software to automatically control articulation of an adjustable base upon which a mattress rests, such as described in U.S. Pat. Nos. 7,555,615 and 7,979,374, the disclosures of which are incorporated herein by reference.

Various alternatives and embodiments are contemplated as being within the scope of the following claims particularly pointing out and distinctly claiming the subject matter regarded as the invention.

1. An interactive product display system comprising:
a display unit for displaying media regarding a product; and
a mounting structure for mounting the display unit to the product in a manner that allows a user to change an orientation of the display unit based on a position of the user.

2. The interactive product display system of claim 1 wherein the mounting structure includes an upright stanchion releasably securable to a bed foundation.

3. The interactive product display system of claim 2 wherein the upright stanchion includes a base, an upright member coupled to the base, and a curved member coupled to the upright member, wherein a portion of the curved member extends outwardly from the upright member.

4. The interactive product display system of claim 3 wherein the display unit is positionable at more than one position relative to the upright member.

5. The interactive product display system of claim 3 further comprising a canopy attached to the curved member.

6. The interactive product display system of claim 5 wherein the canopy is translucent.

7. The interactive product display system of claim 5 wherein the canopy opaque.

8. The interactive product display system of claim 3 wherein the curved ember is rotatably engaged with the upright member.

9. The interactive product display system of claim 1 further comprising a speaker mounted to the mounting structure.

10. The interactive product display system of claim 9 further comprising a canopy attached to the mounting structure.

11. The interactive product display system of claim 1 wherein the display unit includes a touch screen.

12. The interactive product display system of claim 11 wherein the display unit includes an electronic tablet.

13. The interactive product display system of claim 1 wherein the mounting structure engages the top surface of a bed and supports the display unit in a first viewing position and a second viewing position.

14. The interactive product display system of claim 13 wherein the mounting structure includes first leg portion and a second leg portion, and wherein the second leg portion is configured to receive the display unit when the display unit is in the second viewing position.

15. The interactive product display system of claim 13 further comprising a hinge pin interconnecting the display unit to the second leg portion.

16. The interactive product display system of claim first viewing position is opposite the second viewing position.
